(19) United States
(12) Patent Application Publication
(10) Pub. No.: US 2025/0006488 A1
(43) Pub. Date: Jan. 2, 2025

(54) DEPOSITION DEVICE, SEMICONDUCTOR STRUCTURE AND METHOD FOR MANUFACTURING THE SAME

(71) Applicant: NANYA TECHNOLOGY CORPORATION, New Taipei City (TW)

(72) Inventors: Chao-Hsiu LI, New Taipei City (TW); Ji-Feng LIU, New Taipei City (TW)

(21) Appl. No.: 18/341,782

(22) Filed: Jun. 27, 2023

(51) Int. Cl. H01L 21/02; C23C 16/455; H01J 37/32; H01L 23/16; H01L 23/528; H01L 23/532

(52) U.S. Cl. CPC H01L 21/02274; C23C 16/45538; C23C 16/45544; H01J 37/32082; H01L 21/02126; H01L 21/0228; H01L 23/16; H01L 23/528; H01L 23/5329; H01J 2237/327; H01J 2237/3321

(57) ABSTRACT

A deposition device includes a first chamber, a substrate support, a second chamber, a showerhead, a first reactant inlet, a second reactant, and a precursor inlet. The first chamber includes a diffusion zone and a reaction zone, and the diffusion zone is above the reaction zone. The substrate support is disposed in the reaction zone. The second chamber is disposed over the first chamber. The showerhead is disposed between the first chamber and the second chamber. The first reactant inlet communicates with the second chamber. The second reactant inlet communicates with the reaction zone of the first chamber. The precursor inlet communicates with the showerhead.

### BACKGROUND

### Field of Invention

The present disclosure relates to a deposition device, a semiconductor structure, and a method for manufacturing a semiconductor structure.

### Description of Related Art

The integration density of various electronic components, such as transistors, diodes, resistors, capacitors, etc., is being improved continuously in the semiconductor industry by continual reduction in minimum feature sizes. As the feature sizes are decreased, the distance between metal features is continually reduced. As the distance between the metal features reduces, the resulting parasitic capacitance between the metal features increases, leading to higher power consumption and larger resistance-capacitance (RC) time delays for an integrated chip. To improve performance and reduce the parasitic capacitance between the metal features, materials having low dielectric (k) values are used. However, such dielectric materials encounter a lot of processing problems that prevent further improvement of the dielectric constant.

In the process of manufacturing semiconductor devices, there is a need to deposit low-K spacers (LKS) on different substrate surfaces with good uniformity. These different surfaces can constitute different materials, for example a metal and a dielectric. Uniform deposition of one material on two or more different substrate surfaces could be beneficial, for example by reducing the number of steps in device fabrication. There is also a need for dielectric materials with low dielectric constant (k) values and low etch rates, for example in acid-based etching solutions such as HF.

### SUMMARY

The disclosure provides a deposition device. The deposition device includes a first chamber, a substrate support, a second chamber, a showerhead, a first reactant inlet, a second reactant, and a precursor inlet. The first chamber includes a diffusion zone and a reaction zone, and the diffusion zone is above the reaction zone. The substrate support is disposed in the reaction zone. The second chamber is disposed over the first chamber. The showerhead is disposed between the first chamber and the second chamber. The first reactant inlet communicates with the second chamber. The second reactant inlet communicates with the reaction zone of the first chamber. The precursor inlet communicates with the showerhead.

In some embodiments, the deposition device further includes a first power source connected to the second chamber.

In some embodiments, the first power source comprises a radio frequency source and a remote plasma generator coupling to the radio frequency source.

In some embodiments, the deposition device further includes a second power source connected to the showerhead.

In some embodiments, the second power source is a radio frequency source.

In some embodiments, the deposition device further includes a fluid conduit partially covering an outside of the showerhead.

In some embodiments, a fluid transfer fluid flowing in the fluid conduit includes perfluoropolyether.

In some embodiments, the deposition device further includes a pump connected to the first chamber.

The disclosure provides a method for manufacturing a semiconductor structure. The method includes the following steps. A first conductive feature structure is formed over a substrate. A first spacer covers a sidewall of the first conductive feature structure, and a material of the first spacer includes SiCO. A second spacer covers a sidewall of the first spacer, and a material of the second spacer is different from the material of the first spacer. A third spacer covers a sidewall of the second spacer, and a material of the third spacer is different from the materials of the first spacer and the second spacer. A second conductive feature structure is formed adjacent to the third spacer.

In some embodiments, the step of forming the first spacer covering the sidewall of the first conductive feature structure includes the following steps. First, a structure with the first conductive feature structure over the substrate is placed on a substrate support in a deposition device. The deposition device includes a first chamber, a substrate support, a second chamber, a showerhead, a first reactant inlet, a second reactant, and a precursor inlet. The first chamber includes a diffusion zone and a reaction zone, and the diffusion zone is above the reaction zone. The substrate support is disposed in the reaction zone. The second chamber is disposed over the first chamber. The showerhead is disposed between the first chamber and the second chamber. The first reactant inlet communicates with the second chamber. The second reactant inlet communicates with the reaction zone of the first chamber. The precursor inlet communicates with the showerhead. Then, a first reactant gas flows from the first reactant inlet into the second chamber. A second reactant gas flows from the second reactant inlet into the first chamber. A precursor flows from the precursor inlet into the showerhead. Next, an atomic layer deposition is performed so that the first spacer covering the sidewall of the first conductive feature structure.

In some embodiments, the first reactant gas comprises H₂, He, and O₂.

In some embodiments, the second reactant gas comprises NF₃, Ar, and O₂.

The disclosure provides a semiconductor structure. The semiconductor structure includes a substrate, a bit line structure, a first spacer, a second spacer, a third spacer, and a contact. The bit line structure is disposed on the substrate. The first spacer is disposed on a sidewall of the first conductive feature structure, and a material of the first spacer includes SiCO. The second spacer is disposed on a sidewall of the first spacer. The third spacer is disposed on a sidewall of the second spacer. Materials of the second spacer and the third spacer are different from the material of the first spacer. The contact is disposed adjacent to the third spacer.

In some embodiments, the semiconductor structure further includes a landing pad disposed on the bit line structure and the first spacer.

In some embodiments, the landing pad is in direct contact to the bit line structure, the first spacer and the buried contact.

In some embodiments, the landing pad is in direct contact to one portion top surface of the first spacer.

In some embodiments, another portion top surface of the first spacer is exposed.

In some embodiments, the exposed another portion top surface of the first spacer is lower than the one portion top surface of the first spacer contacting with the landing pad.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows.

FIG. 1 is a schematic illustration of a deposition device, in accordance with some embodiments.

FIG. 2 is a cross-sectional view of a semiconductor structure at one of various formation stages, in accordance with some embodiments.

FIG. 3 is a cross-sectional view of a semiconductor structure at one of various formation stages, in accordance with some embodiments.

FIG. 4 is a cross-sectional view of a semiconductor structure at one of various formation stages, in accordance with some embodiments.

FIG. 5 is a cross-sectional view of a semiconductor structure at one of various formation stages, in accordance with some embodiments.

FIG. 6 is a cross-sectional view of a semiconductor structure at one of various formation stages, in accordance with some embodiments.

FIG. 7 is a cross-sectional view of a semiconductor structure at one of various formation stages, in accordance with some embodiments.

FIG. 8 is a cross-sectional view of a semiconductor structure, in accordance with some embodiments.

### DETAILED DESCRIPTION

Reference will now be made in detail to the present embodiments of the present disclosure, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

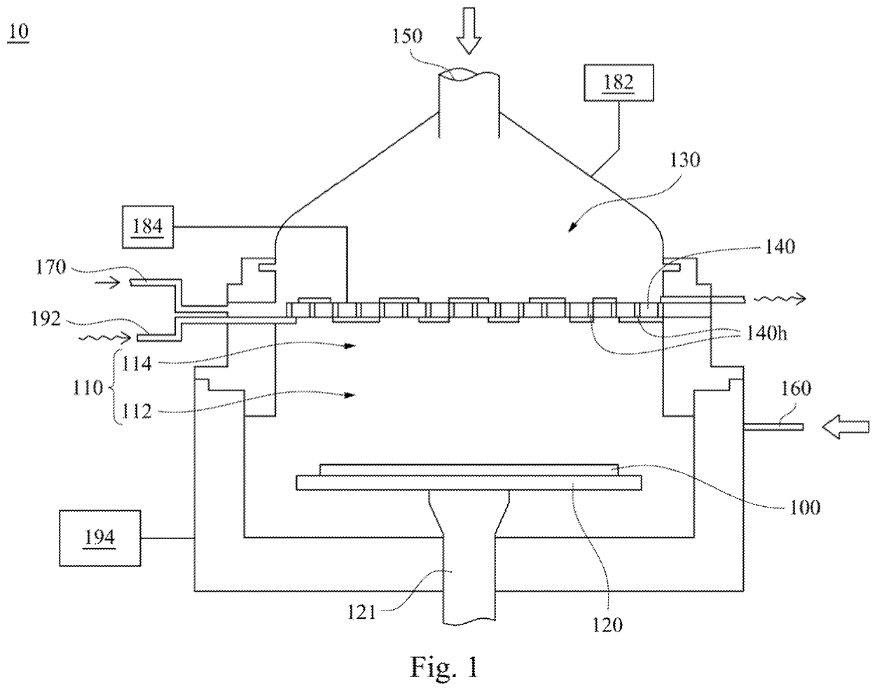

FIG. 1 is a schematic illustration of a deposition device 10, in accordance with some embodiments. To be specific, the deposition device 10 is a chemical vapor deposition (CVD) device. The deposition device 10 is adapted to perform a chemical vapor deposition process (hereinafter referred to as a deposition process) on a substrate 100. The substrate 100 may include a semiconductor layer, a conductive layer, and/or an insulating layer. In some embodiments, substrate 100 includes a stacked semiconductor layer. For example, the substrate 100 includes a stack of semiconductor layers on an insulator, such as a germanium crystal structure over an insulator (SOI), a germanium crystal structure over a sapphire substrate, or a germanium structure over an insulator. The substrate 100 includes a stack of semiconductor layers on a glass to form a thin film transistor.

According to some embodiments, the deposition device 10 is a plasma chemical vapor deposition device such as a remote high density plasma atomic layer deposition (RHDALD). Referring to FIG. 1, the deposition device 10 includes a first chamber 110, a substrate support 120, a second chamber 130, a showerhead 140, a first reactant inlet 150, a second reactant inlet 160, and a precursor inlet 170. More specifically, the first chamber 110 includes diffusion zone 114 and a reaction zone 112, and the diffusion zone 114 is above the reaction zone 112.

Referring to FIG. 1, the substrate support 120 is disposed in the reaction zone 112. The substrate support 120 is used to support a substrate 100. The substrate support 120 typically includes a heating element (not shown). Preferably, the substrate support 120 is movably disposed in the p reaction zone 112 by a stem 121 which extends through the bottom of the first chamber 110 where it is connected to a drive system (not shown). Internally movable lift pins (not shown) are provided in the substrate support 120 to engage a lower surface of the substrate 100. A support ring (not shown) is also provided above the substrate support 120. The support ring may be part of a multi-component substrate support assembly that includes a cover ring and a capture ring. The lift pins act on the ring to receive a substrate 100 before processing, or to lift the substrate 100 after deposition for transfer to the next station.

Although not all specifically shown in detail, the first chamber 110 and the second chamber 130 are typically coupled to facilities when installed in either a clean room or a fabrication facility. Facilities include plumbing that provide, among other things, processing gases, vacuum, temperature control, and environmental particle control. These facilities are coupled to the first chamber 110 and the second chamber 130, when installed in the target fabrication facility. Additionally, the first chamber 110 may be coupled to a transfer chamber that will enable robotics to transfer substrates (e.g., semiconductor wafers) into and out of the first chamber 110 using automation.

Referring to FIG. 1, the second chamber 130 is disposed over the first chamber 110. The showerhead 140 is disposed between the first chamber 110 and the second chamber 130. In some embodiments, the showerhead 140 includes aluminum, aluminum alloy (e.g., 5083 or 6063 aluminum alloy), stainless steel (e.g., stainless steel 304 or 316), hastelloy (e.g., hastelloy C22) or titanium. In some embodiments, the showerhead 140 is heated to about 120° C.-300° C., such as about 180° C. during depositing process. In some embodiments, the temperature of the showerhead 140 may be, for example but is not limited to, about 120° C., 130° C., 140° C., 150° C., 160° C., 170° C., 180° C., 190° C., 200° C., 210° C., 220° C., 230° C., 240° C., 250° C., 260° C., 270° C., 280° C., 290° C., or 300° C., including any range between any two of the preceding values. The showerhead 140 is provided with a plurality of dispensing holes 140h through which process gas or purge gas flows. In some embodiments, the dispensing holes 140h are arranged in an array. With the dispensing holes 140h, the reaction gas uniformly flows toward the diffusion zone 114.

Referring to FIG. 1, the first reactant inlet 150 communicates with the second chamber 130. In some embodiments, a first reactant gas flow into the second chamber 130 from the first reactant inlet 150. For example, the first reactant gas includes H₂, He, and O₂. In some embodiments, the deposition device 10 further includes a first power source 182 connecting to the second chamber 130. For example, the first power source 182 includes a radio frequency (RF) source and a remote plasma generator coupling to the radio frequency source. In some examples, the remote plasma generator includes a microwave-based remote plasma generator, a plasma tube or other type of remote plasma generator. The first power source 182 is configured to convert the first reactant gas into high density plasma radicals.

Referring to FIG. 1, the second reactant inlet 160 communicates with the reaction zone 112 of the first chamber 110. In some embodiments, a second reactant gas flow into the reaction zone 112 from the second reactant inlet 160. For example, the second reactant gas includes NF₃, Ar, and O₂. The precursor inlet 170 communicates with the showerhead 140. In some embodiments, the deposition device 10 further includes a second power source 184 connecting to the showerhead 140. For example, the second power source 184 includes radio frequency (RF) source. The second power source 184 is configured to convert the precursor into plasma radicals.

In some embodiments, the deposition device 10 further includes a fluid conduit 192 partially covering an outside of the showerhead 140. More specifically, a transfer fluid flowing in the fluid conduit 192 includes perfluoropolyether. The fluid conduit 192 has a serpentine shape in top view, consisting of a series of parallel equally spaced pipelines. In other words, the fluid conduit 192 is defined by a continuous pipeline that traces a path back and forth over the process region.

In some embodiments, the deposition device 10 further includes a pump 194 connecting to the first chamber 110. The pump 194 may be used to control pressure and/or evacuate reactants from the first chamber 110. More specifically, gases (e.g. process gases, inert gas, reaction byproducts, etc.) are evacuated from the diffusion zone 114 by the vacuum pump 194. It will be appreciated that the diffusion zone 114 and the reaction zone 112 can be maintained under vacuum by the vacuum pump 194.

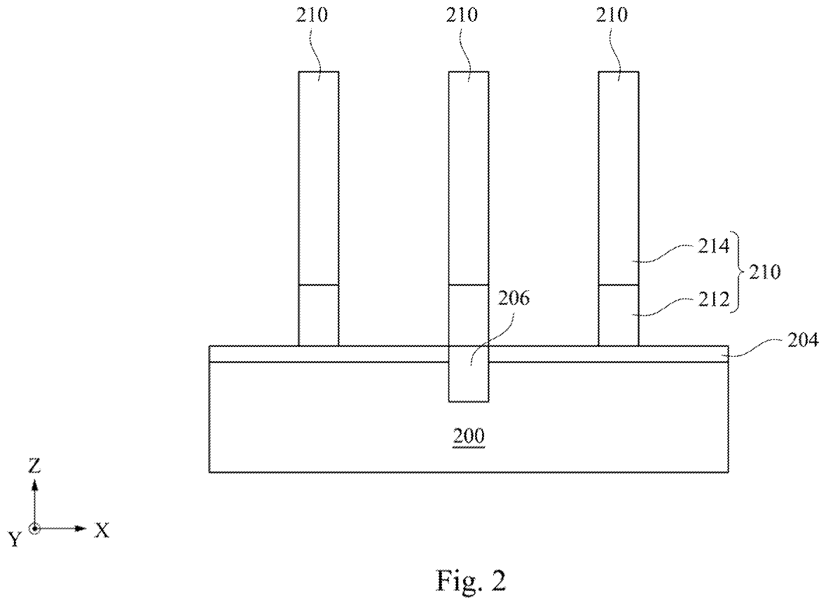

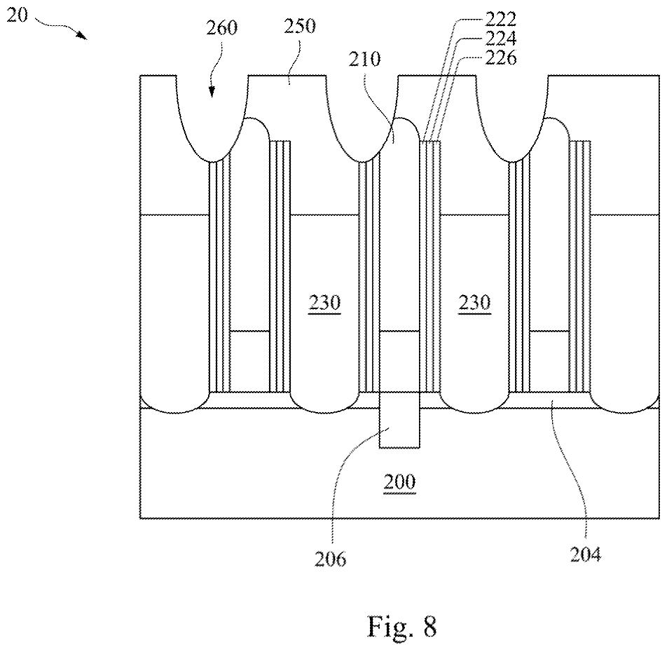

According to another aspect of the present disclosure, a method for manufacturing a semiconductor structure (e.g., semiconductor structure 20 shown in FIG. 8) is provided. FIGS. 2-8 are cross-sectional views of a semiconductor structure at various formation stages, in accordance with some embodiments.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

Referring to FIG. 2, a first conductive feature structure 210 is formed over a substrate 200. In some embodiments, the first conductive feature structure 210 may be a bit line structure. In some embodiments, a plurality of bit line structures 210 protrudes from the substrate 200 as shown in FIG. 2.

The substrate 200 may include a plurality of isolation areas (not shown) and a plurality of active areas (not shown). More specifically, the active areas are spaced apart by the isolation areas. The substrate 200 may include, for example, silicon (e.g., polycrystalline silicon, crystalline silicon, or amorphous silicon). In some embodiments, the substrate 200 may include other elementary semiconductor such as germanium. In some embodiments, the substrate 200 may include an alloy semiconductor such as silicon germanium carbide, silicon germanium, gallium indium phosphide and the like. In some embodiments, the substrate 200 may include compound semiconductor such as silicon carbide, gallium arsenic, indium phosphide, indium arsenide and the like. Further, the substrate 200 may optionally include a semiconductor-on-insulator (SOI) structure.

In some embodiments, the isolation areas may be formed through a shallow trench isolation (STI) process. The isolation areas may include, for example, a material including at least one of silicon oxide, silicon nitride, and silicon oxynitride. The isolation areas may be a single layer including one kind of insulator, a double layer including two kinds of insulators, or a multilayer including a combination of at least three kinds of insulators. For example, the isolation areas may include silicon oxide and silicon nitride. For example, the isolation areas may include a triple layer including silicon oxide, silicon nitride, and silicon oxynitride.

In some embodiments, an insulation layer 204 is formed over the substrate 200 to cover a top surface of the active area and isolation area within the substrate 200. The insulation layer 204 is made of any suitable dielectric material, such as silicon oxide, boro-phospho silicate glass (BPSG), or traethylorthosilicate(TEOS), but the present disclosure is not limited to the above material.

During a formation of the insulation layer 204, an opening (not shown) may expose a portion of active area of the substrate 200 and define a direct contact 206. The opening (not shown) is then filled with a conductive material to form the direct contact 206. The direct contact 206 directly contacts the portion of the active area of the substrate 200, leading to an electrical connection between the direct contact 206 and the active area.

In some embodiments, a plurality of first conductive feature structure 210 (e.g., bit line structures) protrudes from the substrate 200 as shown in FIG. 2. The first conductive feature structure 210 may be regularly arranged at substantially equal intervals from each other over the substrate 200. The first conductive feature structure 210 may further include two portions along a vertical direction substantially perpendicular to the substrate 200 (e.g., along Z direction): a conductive layer 212 at lower portion, and an insulation layer 214 at upper portion.

The formation of the conductive layer 212 and the insulation layer 214 may include forming a conductive material layer and an insulation material layer sequentially over the substrate 200. The insulation material layer may be formed on the conductive material layer. In one embodiment, both of the conductive material layer and the insulation material layer may be substantially simultaneously etched to form the conductive layer 212 and the insulation layer 214. Thus, the first conductive feature structure 210 including the conductive layer 212 and the insulation layer 214 may be spaced apart from each other in a first direction (e.g., the X direction) and extend in parallel with each other along a second direction (e.g., the Y direction). In yet another embodiment, the insulation material layer is etched with desirable patterned and served as a mask pattern on the conductive material layer. Using the patterned insulation material layer as an etch mask, the conductive material layer is etched to form the conductive layer 212.

In some embodiments, the conductive layer 212 includes at least one material selected from semiconductor with impurities doped thereon, metal, conductive metal nitride, and metal silicide. In some embodiments, the conductive layer 212 may have a stacked structure. For example, the conductive layer 212 may be stacked with materials including doped polysilicon as well as metal nitride or metal such as tungsten, tungsten nitride, and/or titanium nitride.

In some embodiments, the insulation layer 214 includes silicon nitride. A vertical length (e.g., a length along the Z axis) of the insulation layer 214 may be greater than that of the conductive layer 212.

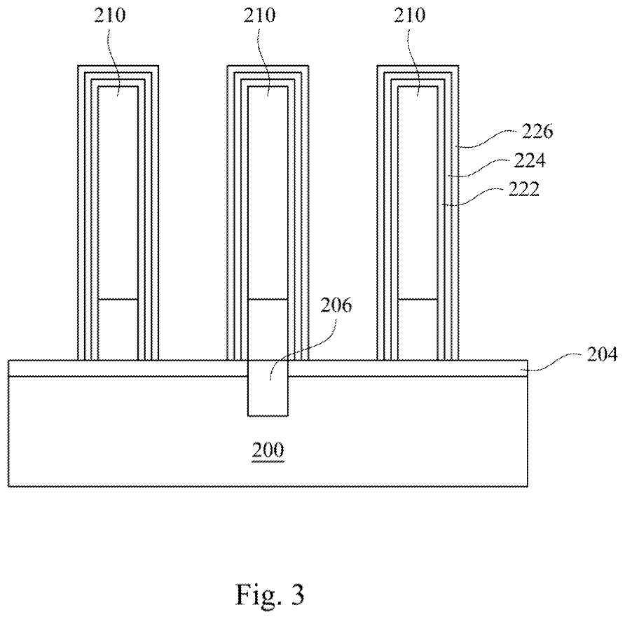

Referring to FIG. 3, a first spacer 222 is formed to cover a sidewall of the first conductive feature structure 210. To be specific, a material of the first spacer 222 includes SiCO. In one embodiment, the first spacer 222 consists of SiCO. Then, a second spacer 224 covers a sidewall of the first spacer 222. To be specific, a material of the second spacer 224 is different from the material of the first spacer 222. In one embodiment, the material of the second spacer 224 includes oxide. For example, the second spacer 224 may include a silicon oxide layer. Next, a third spacer 226 covers a sidewall of the second spacer 224. To be specific, a material of the third spacer 226 is different from the materials of the first spacer 222 and the second spacer 224. In one embodiment, the material of the third spacer 226 includes nitride. For example, the third spacer 226 may include silicon nitride.

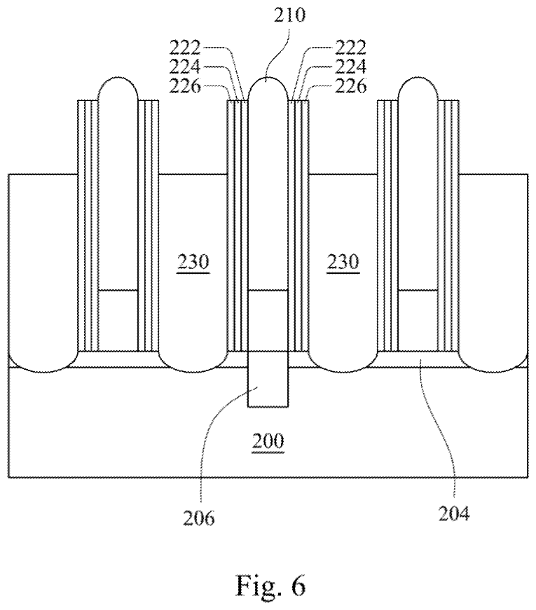

It should be noted that the first spacer 222 consists of SiCO for the SiCO with a dielectric constant (k) of approximate 4.3 reducing parasitic capacitance between the first conductive feature 210 and the second conductive feature structure 230 (shown in FIG. 6) formed subsequently. The first spacer 222 formed by the deposition device 10 of the present disclosure may reduce plasma induced damage (PID) to prevent semiconductor structure damage and reduce film pinhole, thereby having better conformity. The SiCO film without pinhole have excellent wet etch selectivity to resist subsequent process (such as etch and/or clean) and superior hermeticity to protect underlayer (e.g., metal oxidation). Replacing the original SiN film (k value about 7.6) with SiCO low-k film not only has lower k (about 4.3) to reduce parasitic capacitance but has better film quality.

The first spacer 222 is formed by the aforementioned deposition device 10 (shown in FIG. 1). First, a structure with the first conductive feature structure 210 is placed over the substrate 200 on the substrate support 120 in a deposition device 10. The deposition device 10 has been described as relevant in FIG. 1, and therefore no further descriptions are elaborated therein. A first reactant gas is then flows from the first reactant inlet 150 into the second chamber 130. In some embodiments, the first reactant gas includes H₂, He, and O₂. A second reactant gas flows from the second reactant inlet 160 into the first chamber 110. In some embodiments, the second reactant gas includes NF₃, Ar, and O₂. A precursor flows from the precursor inlet 170 into the showerhead 140. Next, an atomic layer deposition is performed in the deposition device 10 thereby forming the first spacer 222 covering the sidewall of the first conductive feature structure 210.

The second spacer 224 and the third spacer 226 may be formed by any suitable deposition approaches such as chemical vapor deposition (CVD) techniques, atomic layer deposition (ALD), or physical vapor deposition (PVD) techniques. In other embodiment, any suitable etching approaches such as reactive ion etching (RIE) techniques may be implemented on the first spacer 222, the second spacer 224, and/or the third spacer 226 to form a particular configuration depending on a design of a semiconductor device. For example, the second spacer 224 may not be as high as the first spacer 222 and/or the third spacer 226.

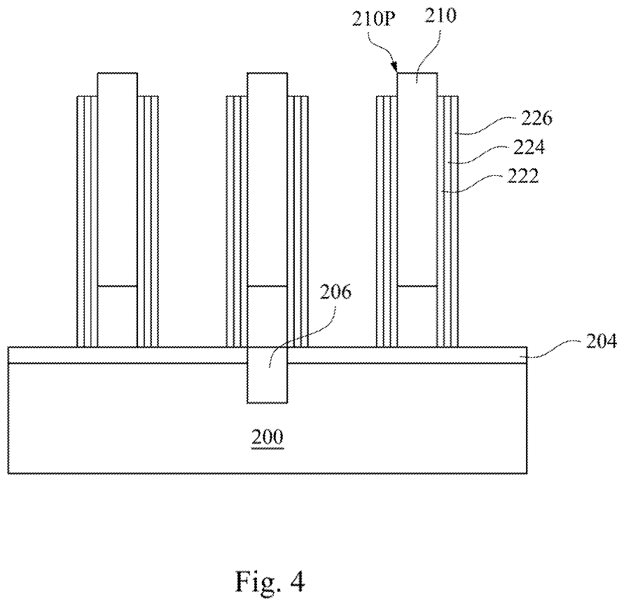

Referring to FIG. 4, the first spacer 222, the second spacer 224 and the third spacer 226 may be etched to expose a portion 210p of the first conductive feature 210, in some embodiments. Alternatively, the first spacer 222, the second spacer 224 and the third spacer 226 may be etched to expose a top surface of the first conductive feature 210, in other embodiment. In another words, top surfaces of the first spacer 222, the second spacer 224 and the third spacer 226 may be leveled with the top surface of the first conductive feature 210.

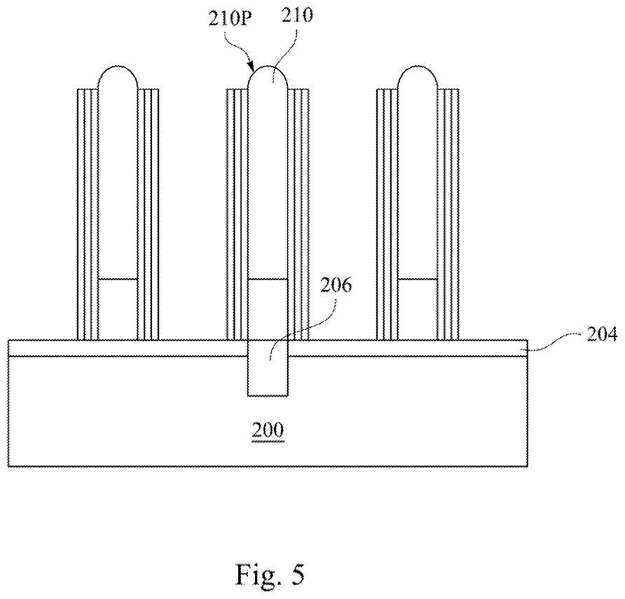

Referring to FIG. 5, the portion 210p of the first conductive feature 210 may form a curved surface or a relatively rounded surface after the etching process. In another words, the top surface of the first conductive feature 210 is not a flat surface. In some embodiments, the configuration of the curved surface shown in FIG. 5 is for a purpose of illustration only. In accordance with some other embodiments of the present disclosure, other configurations may be formed with different parameters in the etching process.

Referring to FIG. 6, a second conductive feature structure 230 is formed adjacent to the third spacer 226. In some embodiments, the second conductive feature structure 230 may be a buried contact. To be specific, the second conductive feature structure 230 is disposed between the adjacent the first conductive feature structure 210 and is in direct contact with the third spacer 226. The second conductive feature structure 230 includes a silicon-containing material. In some embodiments, the second conductive feature structure 230 may include doped polysilicon.

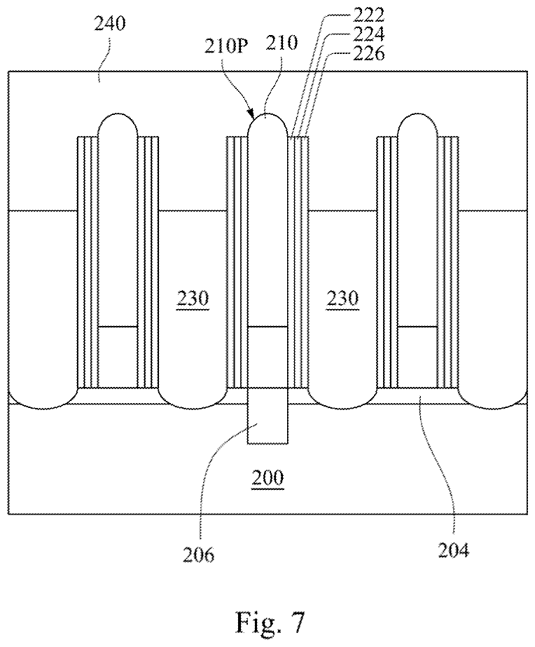

Referring to FIG. 7, a landing pad material 240 is formed on the first conductive feature structure 210 and between two adjacent first conductive feature structures 210. In some embodiments, a top surface of the landing pad material 240 is higher than a top surface of the first conductive feature structure 210. To be specific, the landing pad material 240 covers the portion 210p of the first conductive feature structure 210 and side surfaces and top surfaces of the first spacer 222, the second spacer 224 and the third spacer 226.

In some embodiments, the landing pad material 240 includes a conductive material. For example, the conductive material is a void-free structure. To achieve the void-free structure, forming the conductive material may include several deposition processes and etching processes. In some embodiments, deposition/etch-back/deposition (dep/etch/dep) process is employed to deposit the conductive material into a gap (not shown) between two adjacent first conductive feature structures 210. The dep-etch-dep process involves depositing conductive material, followed by etching some of the conductive material back to widen an opening (not shown) of the gap, and followed by re-depositing conductive material.

The landing pad material 240 may be deposited by using CVD, ALD, PVD, or other suitable deposition process. In some embodiments, a deposition temperature used in the deposition process is in a range of about 280° C. to about 320° C. For example, the deposition temperature used in the deposition process can be 280° C., 290° C., 300° C., 310° C., or 320° C. The etching process performed after the deposition process includes using any suitable dry etching processes and/or wet etching processes. The landing pad material 240 may be stacked with materials including metal nitride or metal such as tungsten, tungsten nitride, and/or titanium nitride.

Referring to FIG. 8, at least a portion of the landing pad material 240 is removed to form a landing pad 250. A mask pattern (not shown) may be formed on the landing pad material 240. Subsequently, the landing pad material 240 is etched with the mask pattern as an etch mask. In some embodiments, a portion of the first conductive feature structure 210 and the first spacer 222, the second spacer 224 and the third spacer 226 disposed on the sidewalls thereof or a portion of the landing pad material 240 may be removed as well. After etching, the landing pad 250 is formed and may be separated from each other by a hole 260. Furthermore, the landing pad 250 is formed based on the landing pad material 240. Thus, the landing pad 250 may include the void-free structure.

According to yet aspect of the present disclosure, a semiconductor structure 20 is provided. FIG. 8 is cross-sectional views of a semiconductor structure 20, in accordance with some embodiments. The semiconductor structure 20 includes a substrate 200, a bit line structure 210, a first spacer 222, a second spacer 224, a third spacer 226, and a buried contact 230. The bit line structure 210 is disposed on the substrate 200. The first spacer 222 is disposed on a sidewall of the bit line structure 210. The material of the first spacer 222 includes SiCO. The second spacer 224 is disposed on a sidewall of the first spacer 222. The third spacer 226 is disposed on a sidewall of the second spacer 224. The materials of the second spacer 224 and the third spacer 226 are different from the material of the first spacer 222. The buried contact 230 is disposed adjacent to the third spacer 226.

In some embodiments, the semiconductor structure 20 further includes a landing pad 250 disposed on the bit line structure 210, the first spacer 222, the second spacer 224, the third spacer 226, and the buried contact 230. The landing pad 250 is in direct contact to the bit line structure 210, the first spacer 222 and the buried contact 230. More specifically, the landing pad 250 is in direct contact to one portion top surface of the first spacer 222 and another portion top surface of the first spacer 222 is exposed. In some embodiments, the exposed another portion top surface of the first spacer 222 is lower than the one portion top surface of the first spacer 222 contacting with the landing pad 250. The materials and forming methods of each element have been described in detail above, and will not be repeated here.

The original SiN spacer in the semiconductor structure is replaced with a SiCO spacer by a novel deposition device of the present disclosure to reduce parasitic capacitance. In addition, the SiCO spacer formed by the novel deposition device of the present disclosure may reduce plasma induced damage to prevent semiconductor structure damage and reduce film pinhole, thereby having better conformity and film quality.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A deposition device, comprising:
a first chamber comprising a diffusion zone and a reaction zone, wherein the diffusion zone is above the reaction zone;
a substrate support disposed in the reaction zone;
a second chamber disposed over the first chamber;
a showerhead disposed between the first chamber and the second chamber;
a first reactant inlet communicating with the second chamber;
a second reactant inlet communicating with the reaction zone of the first chamber; and
a precursor inlet communicating with the showerhead.

2. The deposition device of claim 1, further comprising a first power source connected to the second chamber.

3. The deposition device of claim 2, wherein the first power source comprises a radio frequency source and a remote plasma generator coupling to the radio frequency source.

4. The deposition device of claim 1, further comprising a second power source connected to the showerhead.

5. The deposition device of claim 4, wherein the second power source is a radio frequency source.

6. The deposition device of claim 1, further comprising a fluid conduit partially covering an outside of the showerhead.

7. The deposition device of claim 6, wherein a fluid transfer fluid flowing in the fluid conduit comprises perfluoropolyether.

8. The deposition device of claim 1, further comprising a pump connected to the first chamber.

9. A method for manufacturing a semiconductor structure, comprising:
forming a first conductive feature structure over a substrate;
forming a first spacer covering a sidewall of the first conductive feature structure, wherein a material of the first spacer comprises SiCO;
forming a second spacer covering a sidewall of the first spacer, wherein a material of the second spacer is different from the material of the first spacer;
forming a third spacer covering a sidewall of the second spacer, wherein a material of the third spacer is different from the materials of the first spacer and the second spacer; and
forming a second conductive feature structure adjacent to the third spacer.

10. The method of claim 9, wherein forming the first spacer covering the sidewall of the first conductive feature structure comprising:
placing a structure with the first conductive feature structure over the substrate on a substrate support in a deposition device, wherein the deposition device comprises:
a first chamber comprising a diffusion zone and a reaction zone, wherein the diffusion zone is above the reaction zone;
the substrate support disposed in the reaction zone;
a second chamber disposed over the first chamber;
a showerhead disposed between the first chamber and the second chamber;
a first reactant inlet communicated with the second chamber;
a second reactant inlet communicated with the reaction zone of the first chamber; and
a precursor inlet communicated with the showerhead;
flowing a first reactant gas from the first reactant inlet into the second chamber;
flowing a second reactant gas from the second reactant inlet into the first chamber;
flowing a precursor from the precursor inlet into the showerhead; and
performing an atomic layer deposition so that the first spacer covering the sidewall of the first conductive feature structure.

11. The method of claim 10, wherein the first reactant gas comprises H₂, He, and O₂.

12. The method of claim 10, wherein the second reactant gas comprises NF₃, Ar, and O₂.

13. A semiconductor structure, comprising:
a bit line structure disposed on a substrate;
a first spacer disposed on a sidewall of the bit line structure, wherein a material of the first spacer comprises SiCO;
a second spacer disposed on a sidewall of the first spacer;
a third spacer disposed on a sidewall of the second spacer, wherein materials of the second spacer and the third spacer are different from the material of the first spacer; and
a buried contact disposed adjacent to the third spacer.

14. The semiconductor structure of claim 13, further comprising a landing pad disposed on the bit line structure and the first spacer.

15. The semiconductor structure of claim 14, wherein the landing pad is in direct contact to the bit line structure, the first spacer and the buried contact.

16. The semiconductor structure of claim 14, wherein the landing pad is in direct contact to one portion top surface of the first spacer.

17. The semiconductor structure of claim 16, wherein another portion top surface of the first spacer is exposed.

18. The semiconductor structure of claim 17, wherein the exposed another portion top surface of the first spacer is lower than the one portion top surface of the first spacer contacting with the landing pad.
